(19) United States
(12) Patent Application Publication
(10) Pub. No.: US 2012/0222743 A1
(43) Pub. Date: Sep. 6, 2012

(54) ORGANIC PHOTOVOLTAIC CELL AND MANUFACTURING METHOD OF THE SAME

(76) Inventors: Takehito Kato, Tochigi (JP); Ken Yoshimura, Ibaraki (JP); Toshihiro Ohnishi, Ibaraki (JP)

(21) Appl. No.: 13/504,653

(22) PCT Filed: Oct. 26, 2010
(86) PCT No.: PCT/JP2010/068954

§ 371 Date: Apr. 27, 2012

(30) Foreign Application Priority Data
Oct. 30, 2009 (JP) 2009-249923

(51) Int. Cl. H01L 51/44; H01L 51/48; H01L 31/18

(52) U.S. Cl. 136/263; 438/57; 257/E31.001

(57) ABSTRACT

An organic photovoltaic cell comprising a pair of electrodes and an active layer that is located between the pair of electrodes and containing an organic compound, in which each content of inorganic compounds of a phosphorus compound, a palladium compound, an aluminum compound, an iron compound, a calcium compound, a potassium compound, and a sodium compound are 30 ppm by weight or less in the active layer, and is excellent in photovoltaic efficiency.

### TECHNICAL FIELD

The present invention relates to an organic photovoltaic cell.

### BACKGROUND ART

Organic photovoltaic cells have advantages such as their simple structures and manufacturing facility at low cost due to reason that organic photovoltaic cells can be formed by printing and the like, in comparison with other cells such as inorganic photovoltaic cells. However, poor photovoltaic efficiency of the organic photovoltaic cell has been hampering the practical use of the cell.

One of the causes for the poor photovoltaic efficiency of the organic photovoltaic cell is insoluble components in a p-type semiconductor material contained in an active layer that constitutes the cell.

Patent Document 1 describes that a compound serving as a p-type semiconductor material is purified by column chromatography using silica gel as a filler, followed by film formation to form a p-type semiconductor layer.

### RELATED ART DOCUMENTS

### Patent Literature

Patent Literature 1: International Publication No. WO 2008/044585

### DISCLOSURE OF THE INVENTION

### Technical Problem

Even though purification with silica gel is performed as in Patent Document 1, however, insoluble components cannot be adequately removed from the p-type semiconductor material, and therefore the organic photovoltaic cell may generate leakage currents, which make it difficult to enhance photovoltaic efficiency.

According to the present invention, by purifying an electron donor compound with a particular adsorbent, an organic photovoltaic cell that comprises an active layer in which the contents of inorganic compounds are certain amounts or less is obtained. The organic photovoltaic cell is excellent in photovoltaic efficiency.

The present invention provides [1] to [6] below.

[1] An organic photovoltaic cell comprising:

a pair of electrodes; and

an active layer located between the pair of electrodes and comprising an organic compound, wherein

in the active layer, each content of inorganic compounds of a phosphorus compound, a palladium compound, an aluminum compound, an iron compound, a calcium compound, a potassium compound, and a sodium compound is 30 ppm by weight or less.

[2] The organic photovoltaic cell according to above [1], wherein the organic compound is an electron-donor compound that is purified using an adsorbent comprising silica gel and alumina.
[3] An organic photovoltaic cell comprising:

a pair of electrodes; and

an active layer located between the pair of electrodes and comprising an organic compound, wherein

a content of a palladium compound in the active layer is 30 ppm by weight or less in terms of palladium.

[4] An organic photovoltaic cell comprising:

a pair of electrodes; and

an active layer located between the pair of electrodes and comprising an organic compound, wherein

a content of a sodium compound in the active layer is 30 ppm by weight or less in terms of sodium.

[5] An organic photovoltaic cell comprising:

a pair of electrodes; and

an active layer located between the pair of electrodes and comprising an organic compound, wherein

content of an iron compound in the active layer is 30 ppm by weight or less in terms of iron.

[6] A manufacturing method of an organic photovoltaic cell comprising a pair of electrodes and an active layer that is located between the pair of electrodes and comprises an organic compound, the manufacturing method comprising:

purifying an electron-donor compound serving as the organic compound with an adsorbent comprising silica gel and alumina; and

forming a film of the active layer using a liquid comprising an organic compound that comprises the electron-donor compound after being purified.

### BRIEF DESCRIPTION OF DRAWINGS

FIG. 1 depicts an example of a layer structure of an organic photovoltaic cell according to the present invention.

FIG. 2 depicts another example of a layer structure of the organic photovoltaic cell according to the present invention.

FIG. 3 depicts another example of a layer structure of the organic photovoltaic cell according to the present invention.

FIG. 4 is a graph illustrating the current-voltage characteristics of organic thin-film solar cells of Example 1 and Comparative Example 1.

FIG. 5 is a graph illustrating the current-voltage characteristics of organic thin-film solar cells of Example 2 and Comparative Example 2.

FIG. 6 is a graph illustrating the current-voltage characteristics of an organic thin-film solar cell of Comparative Example 3.

### EXPLANATIONS OF LETTERS OR NUMERALS

10 ORGANIC PHOTOVOLTAIC CELL

20 SUBSTRATE

32 FIRST ELECTRODE

34 SECOND ELECTRODE

40 ACTIVE LAYER

42 FIRST ACTIVE LAYER

44 SECOND ACTIVE LAYER

52 FIRST INTERLAYER

54 SECOND INTERLAYER

### EMBODIMENTS FOR CARRYING OUT THE INVENTION

The scales that are used for the components in the drawings referred to in the following description may be different from the actual ones. The organic photovoltaic cells have components such as lead wires of electrodes and, however, these components are not described or illustrated because of their lack of direct involvement in the description of the present invention.

An organic photovoltaic cell of the present invention has a basic configuration comprising a pair of electrodes and an active layer. At least one of the pair of electrodes is transparent or translucent. In the organic photovoltaic cell, the transparent or translucent electrode out of the pair of electrodes is generally an anode. In the pair of electrodes, the electrode that may be neither transparent nor translucent is usually a cathode. In the organic photovoltaic cell, the active layer is generally located between the pair of electrodes. The active layer may be a monolayer or multilayered. A layer other than the active layer may be located between the pair of electrodes, and this layer may be called an interlayer in the present description.

The active layer is a layer comprising an organic compound. Examples of the organic compound may include electron-donor compounds (p-type semiconductors) and electron-acceptor compounds (n-type semiconductors). The active layer may be a monolayer or a layered body composed of a plurality of layers superimposed. Examples of the configuration of the active layer may include a so-called pn hetero-junction active layer in which a layer (electron-donor layer) formed of the electron-donor compound and a layer (electron-acceptor layer) formed of the electron-acceptor compound are superimposed; a bulk hetero-junction active layer in which the electron-donor compound and the electron-acceptor compound are mixed together to form a bulk hetero-junction structure; and the like. The active layer according to the present invention may have any of these configurations.

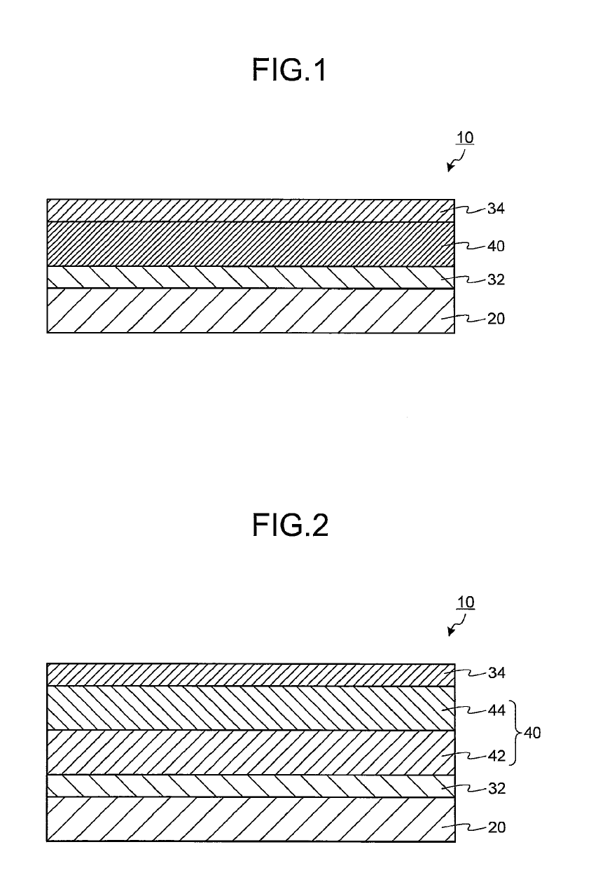

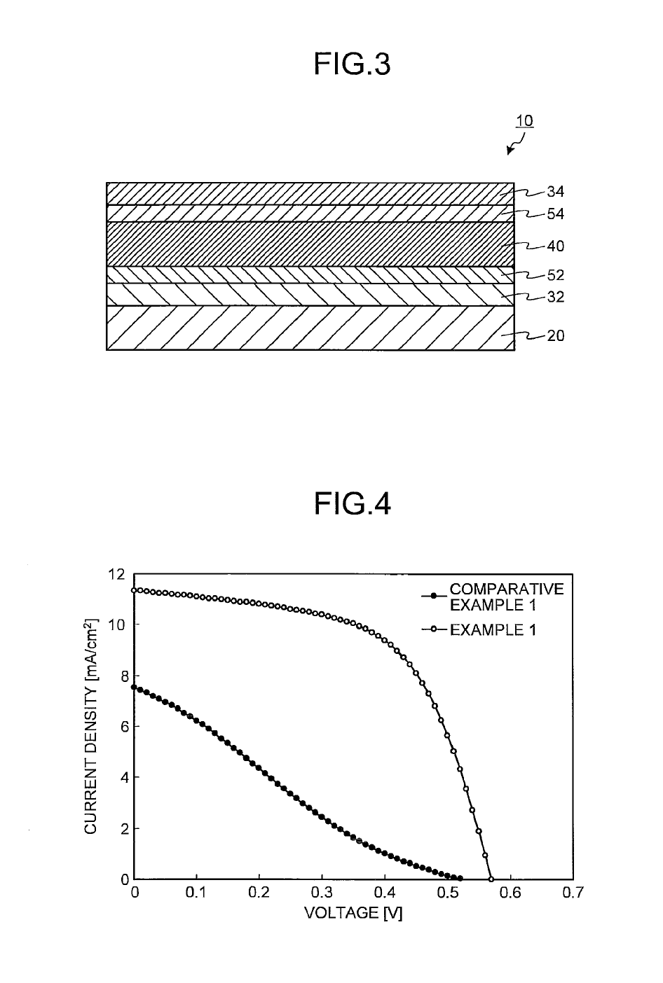

Examples of the layer structure of the organic photovoltaic cell are explained referring to FIGS. 1 to 3. Each of FIGS. 1 to 3 illustrates an example of the layer structure of the organic photovoltaic cell. Hereinafter, FIG. 1 is explained first, FIG. 2 is then explained only on the differences from FIG. 1, and then FIG. 3 is explained only on the differences from FIGS. 1 and 2.

In the case shown in FIG. 1, an active layer 40 is sandwiched and held between a first electrode 32 and a second electrode 34, and the resulting layered body is mounted on a substrate 20 to constitute an organic photovoltaic cell 10. In the case of introducing light from the side of the substrate 20, the substrate 20 is transparent or translucent.

Generally, at least one of the first electrode 32 and the second electrode 34 is transparent or translucent. In the case of introducing light from the side of the substrate 20, the first electrode 32 is transparent or translucent.

There is no particular limitation on which of the first electrode 32 and the second electrode 34 to be an anode or a cathode. In the case of manufacturing the organic photovoltaic cell 10 by stacking sequentially from the side of the substrate 20 and forming a film of the cathode (such as aluminum) by a deposition method, deposition may be preferably carried out in a later step. Therefore, in this case, the first electrode 32 is preferably the anode and the second electrode 34 is preferably the cathode. In this case, it may be difficult depending on the designed thickness thereof to make an aluminum electrode transparent or translucent. Therefore, in order to introduce light from the side of the substrate 20, the substrate 20 and the first electrode 32 are preferably formed to be transparent or translucent.

In the case shown in FIG. 2, the active layer 40 is composed of two layers, namely a first active layer 42 and a second active layer 44, and is a pn hetero-junction active layer. One of the first active layer 42 and the second active layer 44 is the electron-acceptor layer, while the other layer is the electron-donor layer.

In the case shown in FIG. 3, a first interlayer 52 and a second interlayer 54 are provided. The first interlayer 52 is located between the active layer 40 and the first electrode 32, while the second interlayer 54 is located between the active layer 40 and the second electrode 34. Either the first interlayer 52 or the second interlayer 54 alone may be provided. FIG. 3 illustrates each interlayer as a monolayer and, however, the interlayer may be composed of a plurality of layers.

The interlayer may have various functions. When the first electrode 32 is the anode, examples of the first interlayer 52 may include a hole transport layer, an electron block layer, a hole injection layer, and a layer having other functions. In this case, the second electrode 34 is the cathode, and examples of the second interlayer 54 may include an electron transport layer, an electron block layer, or a layer having other functions. By contrast, when the first electrode 32 is the cathode and the second electrode 34 is the anode, the interlayers swap their positions.

The organic photovoltaic cell of the present invention is the organic photovoltaic cell described above, in which a content of an inorganic compound in the active layer is 30 ppm by weight or less.

Example of the inorganic compounds may include phosphorus compounds, palladium compounds, aluminum compounds, iron compounds, calcium compounds, potassium compounds, and sodium compounds. Examples of the organic photovoltaic cells in the present invention may include organic photovoltaic cells in which, in the active layer, the content of palladium compound(s) is 30 ppm by weight or less in terms of palladium, the content of sodium compound(s), which are sodium-containing compound(s), is 30 ppm by weight or less in terms of sodium, and the content of iron compound(s), which are iron-containing compound(s), is 30 ppm by weight or less in terms of iron.

These contents of the inorganic compounds in the active layer are interpreted that each inorganic compound comprises each inorganic element, such as phosphorus, palladium, aluminum, iron, calcium, potassium, and sodium, at 30 ppm by weight or less, preferably 10 ppm by weight or less, and more preferably 1 ppm by weight or less. The content in the active layer being 30 ppm by weight or less leads to reduce charge trapping in the organic photovoltaic cell and prevent degradation in performance, and therefore an organic photovoltaic cell excellent in photovoltaic efficiency can be obtained. The lower limit to the content of the inorganic compound in the active layer, in terms of the total amount of inorganic elements in the inorganic compound, is not particularly limited and is usually 0.01 ppm by weight or more. In the present invention, the unit “ppm” represents “ppm by weight.”

The active layer is a layer comprising an organic compound. Examples of the organic compound in the active layer may include a combination of the electron-donor compound and the electron-acceptor compound, as described above. The electron-donor compound and the electron-acceptor compound are not particularly limited and can be determined relative to each other depending on the energy levels of these compounds.

Examples of the electron-donor compound may include pyrazoline derivatives, arylamine derivatives, stilbene derivatives, triphenyldiamine derivatives, oligothiophenes and derivatives thereof, polyvinylcarbazole and derivatives thereof, polysilane and derivatives thereof, polysiloxane derivatives having an aromatic amine in a side chain or a main chain, polyaniline and derivatives thereof, polythiophene and derivatives thereof, polypyrrole and derivatives thereof, polyphenylenevinylene and derivatives thereof, polythienylenevinylene and derivatives thereof, and the like. Among these, oligothiophenes and derivatives thereof are preferable and poly(3-hexylthiophene) (P3HT) is more preferable.

As the electron-donor compound, compounds having a structural unit represented by Formula (1) are also preferable.

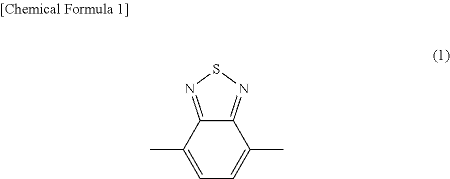

The compound having the structural unit represented by Formula (1) preferably has a structural unit represented by Formula (2) as well.

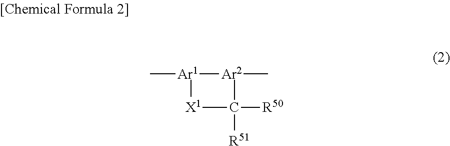

In Formula (2), Ar¹ and Ar² are the same as or different from each other, and each represents a trivalent heterocyclic group. X¹ represents —O—, —S—, —C(═O)—, —S(═O)—, —SO₂—, —Si(R³) (R⁴)—, —N(R⁵)—, —B(R⁶)—, —P(R⁷)—, or —P(═O)(O)—.

R³, R⁴, R⁵, R⁶, R⁷, and R⁵ are the same as or different from each other, and each represents a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an imino group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group, or a cyano group. R⁵⁰ represents a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an imino group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group, or a cyano group. R⁵¹ represents an alkyl group having 6 or more carbon atoms, an alkyloxy group having 6 or more carbon atoms, an alkylthio group having 6 or more carbon atoms, an aryl group having 6 or more carbon atoms, an aryloxy group having 6 or more carbon atoms, an arylthio group having 6 or more carbon atoms, an arylalkyl group having 7 or more carbon atoms, an arylalkyloxy group having 7 or more carbon atoms, an arylalkylthio group having 7 or more carbon atoms, an acyl group having 6 or more carbon atoms, or an acyloxy group having 6 or more carbon atoms. X¹ and Ar² are bonded to adjacent sites on a heterocycle in Ar¹, and C(R⁵⁰)(R⁵¹) and Ar¹ are bonded to adjacent sites on a heterocycle in Ar².

Examples of the compound having the structural unit represented by Formula (1) may include a polymer (hereinafter, called a macromolecular compound A) obtained by polymerizing a compound represented by Formula (3) and a compound represented by Formula (4).

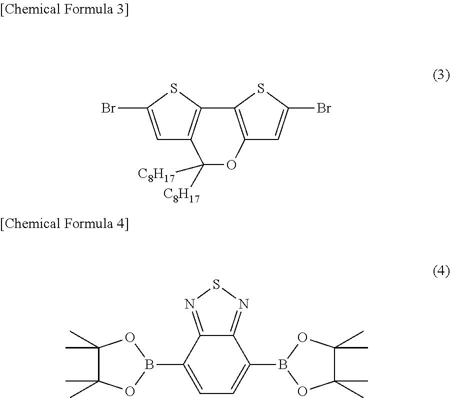

Examples of the compound having the structural unit represented by Formula (1) may also include a polymer (hereinafter, called a macromolecular compound B) represented by Formula (5).

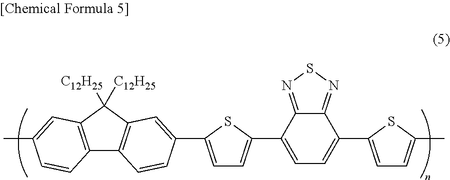

As the electron-donor compound, a macromolecular compound with a polystyrene equivalent weight average molecular weight which is calculated using a polystyrene standard sample, of 3000 to 10000000 is preferably used. When the weight average molecular weight is lower than 3000, a defect may occur in film formation on manufacturing a device, while when it is higher than 10000000, the solubility in solvent or the application property at the time of cell formation may deteriorate. The weight average molecular weight of the electron-donor compound is further preferably 8000 to 5000000 and is particularly preferably 10000 to 1000000.

The electron-donor compound may be used alone or as a combination of two or more of these.

The electron-donor compound is preferably a compound that is purified using an adsorbent comprising both of silica and alumina. By purification, impurities in the electron-donor compound are removed and the content of the inorganic compound in the active layer can be suppressed to be 30 ppm by weight or less, and therefore charge trapping that causes degradation in performance of the organic photovoltaic cell can be reduced, so that photovoltaic efficiency can be enhanced. Conditions in purification using an adsorbent comprising silica gel and alumina are not particularly limited and can be selected, as appropriate, depending on the species and the amount of the compound and other conditions.

Examples of the method of purification using an adsorbent comprising silica and alumina may include methods in which a column filled with silica and alumina is used. An example of these methods is one in which an electron-donor compound is dissolved in a solvent to prepare a liquid, which is made to pass through a column filled with silica and alumina, and out of the resulting liquid, the compound is separated. The solvent that can be used may be either water or an organic solvent. Examples of the organic solvent may include halogenated unsaturated hydrocarbon solvents such as chlorobenzene, dichlorobenzene, and trichlorobenzene; unsaturated hydrocarbon solvents; ether solvents; and the like. Among them, halogenated unsaturated hydrocarbon solvents are preferable, dichlorobenzene is more preferable, and o-dichlorobenzene is further preferable. Examples of the methods of separating the compound after purification may include one in which the liquid that has passed through the column is poured into a hydrophilic solvent such as alcohols (methanol, for example) for precipitation, and one in which the compound obtained by precipitation is further filtrated and is then dried.

Examples of the electron-acceptor compound may include oxadiazole derivatives, anthraquinodimethane and derivatives thereof, benzoquinones and derivatives thereof, naphthoquinones and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and of derivatives of 8-hydroxyquinoline, polyquinolines and derivatives thereof, polyquinoxalines and derivatives thereof, polyfluorene and derivatives thereof, fullerenes such as C₆₀ and fullerene derivatives, phenanthrene derivatives such as bathocuproine, metallic oxides such as titanium oxide, carbon nanotubes, and the like. As the electron-acceptor compound, titanium oxide, carbon nanotubes, fullerenes, and fullerene derivatives are preferable, and fullerenes and fullerene derivatives are particularly preferable.

Examples of the fullerenes may include C₆₀ fullerene, C₇₀ fullerene, C₇₆ fullerene, C₇₈ fullerene, C₈₄ fullerene, and the like.

Examples of the fullerene derivatives may include C₆₀ fullerene derivatives, C₇₀ fullerene derivatives, C₇₆ fullerene derivatives, C₇₉ fullerene derivatives, and C₈₄ fullerene derivatives. Examples of the specific structures of the fullerene derivatives may include the followings.

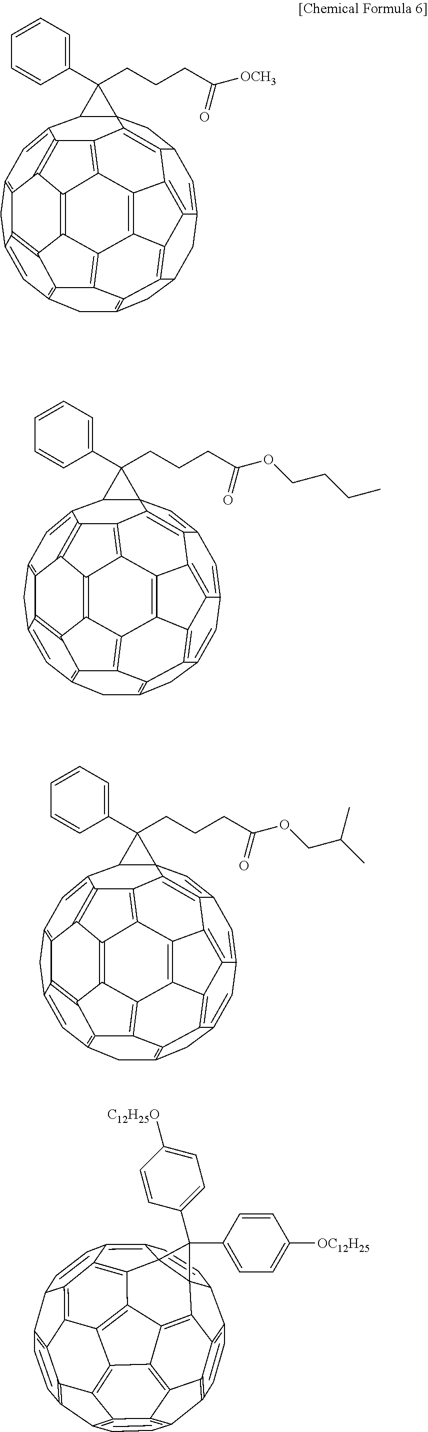

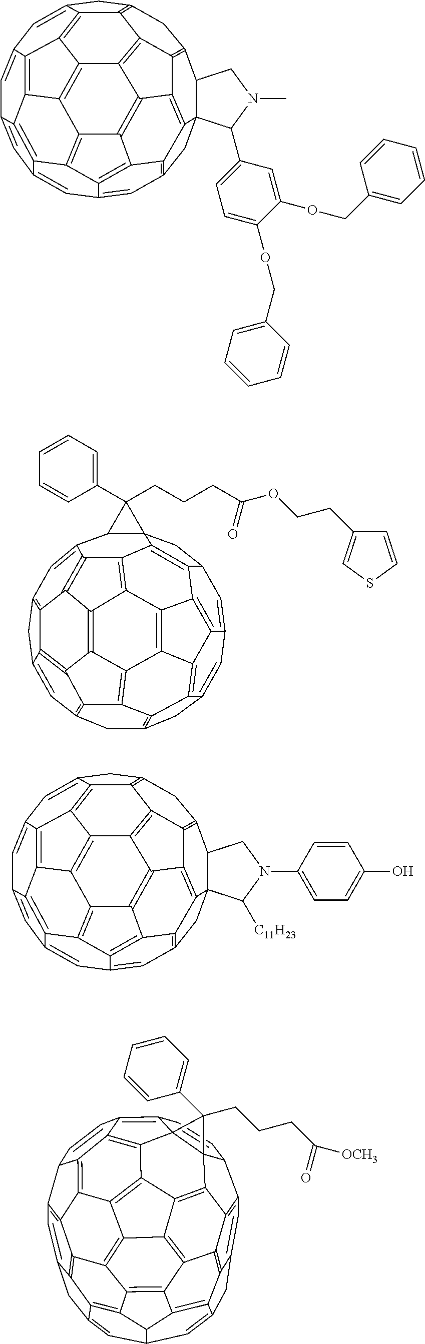

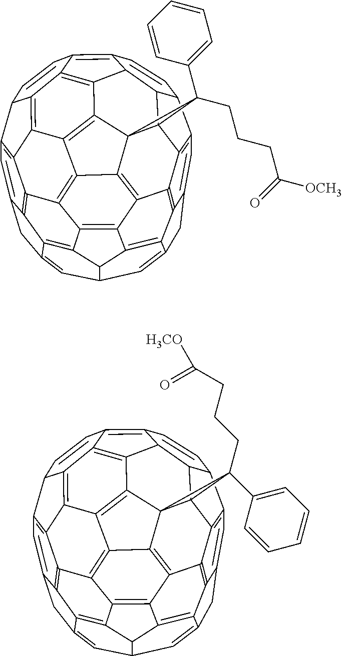

Examples of the fullerene derivatives may include [5,6]-Phenyl C₆₁ butyric acid methyl ester ([5,6]-PCBM), [6,6]-Phenyl C61 butyric acid methyl ester ([6,6]-PCBM, C₆₀PCBM), [6,6]-Phenyl C₇₁ butyric acid methyl ester (C₇₀PCBM), [6,6]-Phenyl C₈₅ butyric acid methyl ester (C₈₄PCBM), [6,6]-Thienyl C₆₁ butyric acid methyl ester, and the like.

As the electron-acceptor compound, among these specific examples, fullerenes and fullerene derivatives are preferable and [5,6]-PCBM and [6,6]-PCBM are more preferable. In the case of using the fullerene derivative as the electron-acceptor compound, the proportion of the fullerene derivative is preferably 10 to 1000 parts by weight and is more preferably 20 to 500 parts by weight, based on 100 parts by weight of the electron-donor compound.

The electron-acceptor compound is not always used alone, and a combination of two or more compounds may be used.

The active layer can be formed by forming a film using the liquid comprising the organic compound. Examples of the methods for achieving it may include a method which comprises purifying an electron-donor compound serving as the organic compound with a silica-alumina column, forming a film using the liquid comprising organic compounds that include the purified electron-donor compound (in other words, the organic compounds includes the purified electron-donor compound and one, two, or more organic compounds other than the purified electron-donor compound) to form the active layer. With this manufacturing method, an organic photovoltaic cell that comprises 30 ppm by weight or less of inorganic compounds can be obtained with high efficiency.

Purification of the electron-donor compound with a silica-alumina column is already described.

The liquid comprising the organic compound can be prepared by dissolving the organic compound in a solvent. The solvent may be selected, as appropriate, depending on the species of the electron-donor compound and the electron-acceptor compound, and examples of the solvent may include water and organic solvents. Examples of the organic solvents may include unsaturated hydrocarbon solvents such as toluene, xylene, mesitylene, tetralin, decalin, bicyclohexyl, n-butylbenzene, sec-butylbenzene, and tert-butylbenzene, halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, and bromocyclohexane, halogenated unsaturated hydrocarbon solvents such as chlorobenzene, dichlorobenzene, and trichlorobenzene, ether solvents such as tetrahydrofuran and tetrahydropyrane, and the like. Among these, halogenated unsaturated hydrocarbon solvents are preferable, dichlorobenzene is more preferable, and ortho-dichlorobenzene is further preferable.

The addition amount of the organic compound in the solvent is not particularly limited and an optimal range thereof can be selected, as appropriate. The addition amount of the organic compound in the solvent is usually 0.1% by weight or more, is preferably 0.2% by weight or more, and is more preferably 0.5% by weight or more.

In the case where the liquid comprising the organic compound is a liquid comprising both of the electron-donor compound and the electron-acceptor compound, the total amount of the electron-donor compound and the electron-acceptor compound in the liquid is usually 0.2% by weight or more, is preferably 0.5% by weight or more, and is more preferably 1% by weight or more. The ratio of the electron-donor compound to the electron-acceptor compound can be adjusted to be usually 1 to 20:20 to 1, is preferably 1 to 10:10 to 1, and is further preferably 1 to 5:5 to 1. In the case of individually preparing a liquid comprising the electron-donor compound and a liquid comprising the electron-acceptor compound, the electron-donor compound or the electron-acceptor compound in the liquid is usually 0.4% by weight or more, is preferably 0.6% by weight or more, and is more preferably 2% by weight or more.

The liquid comprising the organic compound may be filtrated, where appropriate. This can further enhance photovoltaic efficiency. The pore size of the filter is usually 10 to 0.1 μm, is preferably 5 to 0.1 μm, and is more preferably 0.15 to 0.1 μm.

A film of the active layer may be formed by, for example, applying the liquid comprising the organic compound over an electrode or an interlayer, and then volatilizing the solvent. Examples of the method of application may include coating methods.

Examples of the coating methods may include a spin coating method, a casting method, a micro-gravure coating method, a gravure coating method, a bar coating method, a roll coating method, a wire bar coating method, a dip coating method, a spray coating method, a screen printing method, a gravure printing method, a flexo printing method, an offset printing method, an ink-jet printing method, a dispenser printing method, a nozzle coating method, a capillary coating method, and the like. Among them, a spin coating method, a flexo printing method, a gravure printing method, an ink-jet printing method, and a dispenser printing method are preferable, and a spin coating method is more preferable.

In the case of manufacturing an organic photovoltaic cell having a bulk hetero-junction active layer as the active layer, for example, the liquid comprising both of the electron-donor compound and the electron-acceptor compound can be applied over an electrode or an interlayer, followed by volatilizing the solvent to form the active layer.

On the other hand, in the case of manufacturing an organic photovoltaic cell having a pn hetero-junction active layer as the active layer, for example, the liquid comprising the electron-donor compound and the liquid comprising the electron-acceptor compound are prepared, and the liquid comprising the electron-donor compound is applied over an electrode or an interlayer, followed by volatilizing the solvent to form the electron-donor layer. Then, the liquid comprising the electron-acceptor compound is applied over the electron-donor layer, followed by volatilizing the solvent to form the electron-acceptor layer. The active layer having a two-layer structure can be thus formed. The electron-donor layer and the electron-acceptor layer may be formed the other way around.

The thickness of the active layer is usually 1 nm to 100 μm, is preferably 2 nm to 1000 nm, is more preferably 5 nm to 500 nm, and is further preferably 20 nm to 200 nm.

Examples of the manufacturing method of the organic photovoltaic cell of the present invention may include one which comprises forming an electrode on a substrate and then forming an active layer as described above, followed by forming an electrode on the active layer. This method can produce an organic photovoltaic cell shown as examples in FIG. 1 or 2. Alternatively, an electrode can be formed on a substrate, an interlayer can be then formed on the electrode, and then an active layer can be formed as described above, followed by forming an interlayer on the active layer, further forming an electrode on the interlayer. This method can form an organic photovoltaic cell shown as an example in FIG. 3. The method for forming the electrodes can be selected from various methods for forming a thin film, as appropriate, in consideration of conditions such as the species of material for the electrodes and the thickness of electrodes. Likewise, the method for forming the interlayers can be selected from various methods for forming a thin film, as appropriate, in consideration of conditions such as the species of electrodes and the thickness of the electrodes. In the case of forming the electrodes and/or the interlayers by forming a film using a liquid, the coating methods described above and the like may be employed, as appropriate, and a vacuum deposition method, a sputtering method, chemical vapor deposition (CVD), and the like may also be employed. After the electrode is formed on the substrate, the active layer may be formed directly onto the electrode, or, optionally, the active layer may be formed after another step such as heating, UV—O₃ treatment, and exposure to the atmosphere.

The substrate has only not to chemically change at the time of electrode formation and at the time of formation of a layer of the organic substance. Examples of the material for the substrate may include glass, plastic, polymer films, silicon, and the like. When the substrate is opaque, the electrode that is on the other side (namely, the electrode out of the pair of electrodes that is farther from the substrate) is preferably transparent or translucent.

Example of the electrode material for the transparent or translucent electrode may include conductive metallic oxide films, translucent metal thin films, and the like. Specific examples may include films formed using conductive materials such as indium oxide, zinc oxide, tin oxide, and complexes (indium tin oxide (ITO), indium zinc oxide (IZO), and NESA, for example) of two or more of these, and thin films of metals such as gold, platinum, silver, and copper, and films formed using conductive materials such as ITO, indium zinc oxide, and tin oxide are preferable. Examples of the method for forming the electrode may include a vacuum deposition method, a sputtering method, an ion plating method, a plating method, and the like. As the electrode material, organic and transparent conductive films made of polyaniline or a derivative thereof, polythiophene or a derivative thereof, or the like may be used.

The electrode to be paired with the transparent or translucent electrode may be transparent or translucent, or may be neither transparent nor translucent. Examples of the electrode material may include metals, conductive polymers, and the like. Specific examples of the electrode material may include metals such as lithium, sodium, potassium, rubidium, cesium, magnesium, calcium, strontium, barium, aluminum, scandium, vanadium, zinc, yttrium, indium, cerium, samarium, europium, terbium, and ytterbium; alloys of two or more of these metals; alloys of one or more of these metals and one or more metals selected from the group consisting of gold, silver, platinum, copper, manganese, titanium, cobalt, nickel, tungsten, and tin; graphite, and graphite intercalation compounds; and polyaniline and derivatives thereof, and polythiophene and derivatives thereof. Examples of the alloys may include magnesium-silver alloys, magnesium-indium alloys, magnesium-aluminum alloys, indium-silver alloys, lithium-aluminum alloys, lithium-magnesium alloys, lithium-indium alloys, calcium-aluminum alloys, and the like.

Examples of the material for the interlayer may include halides and oxides of alkali metals and alkaline-earth metals such as lithium fluoride (LiF), and the like. Examples of the material for the interlayer may also include fine particles of inorganic semiconductors such as titanium oxide, PEDOT (poly(3,4)ethylenedioxythiophene), and the like. Among them, the interlayer on the anode side is preferably PEDOT and the interlayer on the cathode side is preferably an alkali metal (more preferably LiF).

The general outlines of operation mechanism of the organic photovoltaic cell will be described in the followings. Light energy incoming through the transparent or translucent electrode is absorbed by the electron-acceptor compound (n-type organic semiconductor) such as fullerene derivatives and/or the electron-donor compound (p-type organic semiconductor) such as conjugated macromolecular compounds to generate an exciton that results from binding of an electron with a hole. The resulting exciton moves to reach a hetero junction interface where the electron-acceptor compound and the electron-donor compound are adjacent each other, and then, due to the differences between the HOMO energies and between the LUMO energies at the interface, the electron and the hole are separated to generate charges (the electron and the hole) that can move independently. The resulting charges move to reach the electrodes, respectively, where the charges can be taken to the outside as electrical energy (current).

When light such as sunlight is applied through the transparent or translucent electrode, the organic photovoltaic cell manufactured by the manufacturing method of the present invention generates photovoltaic power between the electrodes and therefore may operate as an organic thin-film solar cell. The organic thin-film solar cells in plurality may be integrated to be used as an organic thin-film solar cell module.

When light is applied through the transparent or translucent electrode while a voltage is applied or no voltage is applied between the electrodes, the organic photovoltaic cell of the present invention generates a photoelectric current and therefore may operate as an organic optical sensor. The organic optical sensors in plurality may be integrated to be used as an organic image sensor.

The organic thin-film solar cell can take on a module structure that is basically the same as that of a conventional solar cell module. A solar cell module generally takes on a structure where a cell is mounted on a supporting substrate made of metal, ceramic, or the like, and is then covered with a filling resin, protective glass, or the like, and light is taken from the opposite side to the supporting substrate. Alternatively, a solar cell module can take on a structure where a transparent supporting substrate made of a transparent material such as tempered glass is used as the supporting substrate, on which a cell is formed, and light is taken from the side of the transparent supporting substrate. Specifically, module structures called a superstraight-type structure, a substrate-type structure, and a potting-type structure, substrate-integrated module structures such as one used in an amorphous silicon solar cell, etc., and the like are known. The module structure of the organic thin-film solar cell of the present invention can be selected, as appropriate, from these module structures depending on the intended use or the place or the environment of use.

The typical module structure called a superstraight-type structure or a substrate-type structure takes on a structure where cells are arranged at regular intervals between supporting substrates each of which is transparent on one side or both sides and has been treated to prevent reflection, adjacent cells are connected with a metal lead, flexible wiring, or the like, and a collecting electrode is mounted on the outer rim to take the generated electric power to the outside. Between the substrate and the cell, in order to protect the cell or to enhance current-collection efficiency, various plastic materials such as ethylene vinyl acetate (EVA), depending on the purpose, may be used as a film or a filling resin. In the case of using the module at a place where the module surface needs no covering made of hard material, such as where there are few impact from the outside of the module, a surface-protection layer can be made of a transparent plastic film or the filling resin can be cured to take on a protective function so as to omit one of the supporting substrates. In order to secure the hermeticity and the rigidity of the module, the edges of the supporting substrate are generally fixed with a metal frame in a sandwich-shape. For the same purpose, in general, the gap between the supporting substrate and the frame is hermetically sealed with sealing material. A solar cell in which a flexible raw material is used as the material for the cell, as the material for the supporting substrate, and as the filling and sealing material can be formed on a curved surface.

In the case of a solar cell having a flexible support made of a polymer film or the like, the cell body can be formed by discharging the support of a roll-shape to sequentially form a cell, cutting the resulting cell into a desired size, and then sealing the edges of the cell with a flexible, moisture-proof raw material. The solar cell having a flexible support can also take on a module structure called “SCAF” that is described in Solar Energy Materials and Solar Cells, 48, p. 383-391. Furthermore, the solar cell having a flexible support can also be used adhesively fixed to curved glass and the like.

When the liquid includes insoluble components and/or dust at the time of film formation of the liquid, a crack may occur on a coated film. Furthermore, insoluble components and/or dust may serve as nuclei to form agglomerated particles. The crack and the agglomerated particles give rise to phenomena such as poor electrical or chemical contact at a junction interface and leakage currents. The present invention can reduce these phenomena to enhance photovoltaic efficiency.

### EXAMPLES

### Example 1

### Formation of Organic Photovoltaic Cell

A glass substrate on which an ITO film was formed at a film thickness of about 150 nm by a sputtering method and was patterned was washed with an organic solvent, an alkaline detergent, and ultrapure water, followed by drying. This substrate was subjected to UV—O₃ treatment in a UV—O₃ device.

A suspension of an aqueous solution (manufactured by H. C. Starck-V TECH Ltd., Bytron P TP AI 4083) obtained by dissolving poly(3,4)ethylenedioxythiophene/polystyrene sulfonic acid in water was filtrated using a filter with a pore diameter of 0.5 microns. A film of the filtrated suspension was formed on the substrate on the ITO side to be a thickness of 70 nm by spin coating, followed by drying in the atmosphere on a hot plate at 200° C. for 10 minutes.

Then, a macromolecular compound A was purified. Namely, it was dissolved in 30 mL of ortho-dichlorobenzene, and the resulting solution was made to pass through an alumina/silica-gel column, followed by pouring the obtained solution into methanol to precipitate a polymer. The polymer was filtrated and was then dried. The contents of inorganic compounds in the macromolecular compound A were as follows: 10 ppm by weight or less for iron, 10 ppm by weight or less for palladium, 10 ppm by weight or less for phosphorus, 14 ppm by weight for sodium, 10 ppm by weight or less for potassium, 10 ppm by weight or less for calcium, and 10 ppm by weight or less for aluminum.

A solution comprising the purified macromolecular compound A and [6,6]-phenyl C61 butyric acid methyl ester ([6,6]-PCBM) at a weight ratio of 1:3 in ortho-dichlorobenzene was prepared. The addition amount of the macromolecular compound A was 0.5% by weight relative to that of ortho-dichlorobenzene. The ortho-dichlorobenzene solution was filtrated using a filter with a pore diameter of 0.2 μm. The resulting extract was subjected to spin coating, and drying was then performed in a N₂ atmosphere.

On the top of the active layer thus formed, a film of LiF was formed at a film thickness of about 2.3 nm, and then a film of Al was formed at a film thickness of about 70 nm, in a resistance heating deposition device, to form an electrode. The glass substrate was sealed using an epoxy resin (rapid-curing Araldite) as a sealant, thereby obtaining an organic thin-film solar cell.

### Example 2

### Formation of Organic Photovoltaic Cell

A glass substrate on which an ITO film was formed at a film thickness of about 150 nm by a sputtering method and was patterned was washed with an organic solvent, an alkaline detergent, and ultrapure water, followed by drying. This substrate was subjected to UV—O₃ treatment in a UV—O₃ device.

A suspension of an aqueous solution (manufactured by H. C. Starck-V TECH Ltd., Bytron P TP AI 4083) obtained by dissolving poly(3,4)ethylenedioxythiophene/polystyrene sulfonic acid in water was filtrated using a filter with a pore diameter of 0.5 microns. A film of the filtrated suspension was formed on the substrate on the ITO side to be a thickness of 70 nm by spin coating, followed by drying in the atmosphere on a hot plate at 200° C. for 10 minutes.

Then, a macromolecular compound B was dissolved in 30 mL of o-dichlorobenzene again, and the resulting solution was made to pass through an alumina/silica-gel column, followed by pouring the obtained solution into methanol to precipitate a polymer. The polymer was filtrated and was then dried, followed by purification. The contents of inorganic compounds in the purified macromolecular compound B were as follows: 10 ppm by weight or less for phosphorus, 10 ppm by weight or less for palladium, 10 ppm by weight or less for aluminum, 10 ppm by weight or less for calcium, 10 ppm by weight or less for potassium, 10 ppm or less for iron, and 10 ppm by weight or less for sodium.

A solution comprising the purified macromolecular compound B and [6,6]-phenyl C61 butyric acid methyl ester ([6,6]-PCBM) at a weight ratio of 1:3 in ortho-dichlorobenzene was prepared. The addition amount of the macromolecular compound B was 1% by weight relative to that of ortho-dichlorobenzene. The solution was filtrated using a filter with a pore diameter of 0.2 The resulting extract was subjected to spin coating, and drying was then performed in a N₂ atmosphere.

Furthermore, on the top of the active layer thus formed, a film of LiF was formed at a film thickness of about 2.3 nm, and then a film of Al was formed at a film thickness of about 70 nm, in a resistance heating deposition device, to form an electrode. The glass substrate was sealed using an epoxy resin (rapid-curing Araldite) as a sealant, thereby obtaining an organic thin-film solar cell.

### Comparative Example 2

### Formation of Organic Photovoltaic Cell

An organic photovoltaic cell was formed in the same manner as in Example 1 except that a macromolecular compound A was not purified. The contents of inorganic compounds in the macromolecular compound A were as follows: 850 ppm by weight for phosphorus, 19 ppm by weight for palladium, 380 ppm by weight or less for aluminum, 110 ppm by weight or less for calcium, 13 ppm by weight or less for potassium, 280 ppm for iron, and 46 ppm by weight for sodium.

### Comparative Example 2

### Formation of Organic Photovoltaic Cell

An organic photovoltaic cell was formed in the same manner as in Example 2 except that a macromolecular compound B was not purified. The contents of inorganic compounds in the macromolecular compound B were as follows: 110 ppm by weight for phosphorus, 580 ppm by weight for palladium, 10 ppm by weight or less for aluminum, 10 ppm by weight or less for calcium, 10 ppm by weight or less for potassium, and 79 ppm by weight for sodium.

### Comparative Example 3

### Formation of Organic Photovoltaic Cell

A glass substrate on which an ITO film was formed at a film thickness of about 150 nm by a sputtering method was patterned was washed with an organic solvent, an alkaline detergent, and ultrapure water, followed by drying. This substrate was then subjected to UV—O₃ treatment in a UV—O₃ device with the ITO-patterned side up.

A suspension of an aqueous solution (manufactured by H. C. Starck-V TECH Ltd., Bytron P TP AI 4083) obtained by dissolving poly(3,4)ethylenedioxythiophene/polystyrene sulfonic acid in water was filtrated using a filter with a pore diameter of 0.5 microns. A film of the filtrated suspension was formed on the substrate on the ITO side to be a thickness of 70 nm by spin coating, followed by drying in the atmosphere on a hot plate at 200° C. for 10 minutes.

Then, poly(3-hexylthiophene) (P3HT) was purified. Namely, it was dissolved in 30 mL of o-dichlorobenzene, and the resulting solution was made to pass through an alumina/silica-gel column, followed by pouring the obtained solution into methanol to precipitate a polymer. The polymer was filtrated and was then dried.

A solution comprising poly(3-hexylthiophene) (P3HT) that is the purified electron-donor polymer material and [6,6]-phenyl C61 butyric acid methyl ester ([6,6]-PCBM) at a weight ratio of 1:0.8 in ortho-dichlorobenzene was prepared. The addition amount of P3HT was 1% by weight relative to that of ortho-dichlorobenzene. The solution was filtrated using a filter with a pore diameter of 0.2 μm. The resulting extract was subjected to spin coating, and drying was then performed in a N₂ atmosphere.

Finally, on the top of the upper surface of the active layer thus formed, a film of LiF was formed at a film thickness of about 2.3 nm, and then a film of Al was formed at a film thickness of about 70 nm, in a resistance heating deposition device, to form an electrode. The glass substrate was sealed using an epoxy resin (rapid-curing Araldite) as a sealant, thereby obtaining an organic thin-film solar cell.

(Evaluation of Photovoltaic Efficiency)

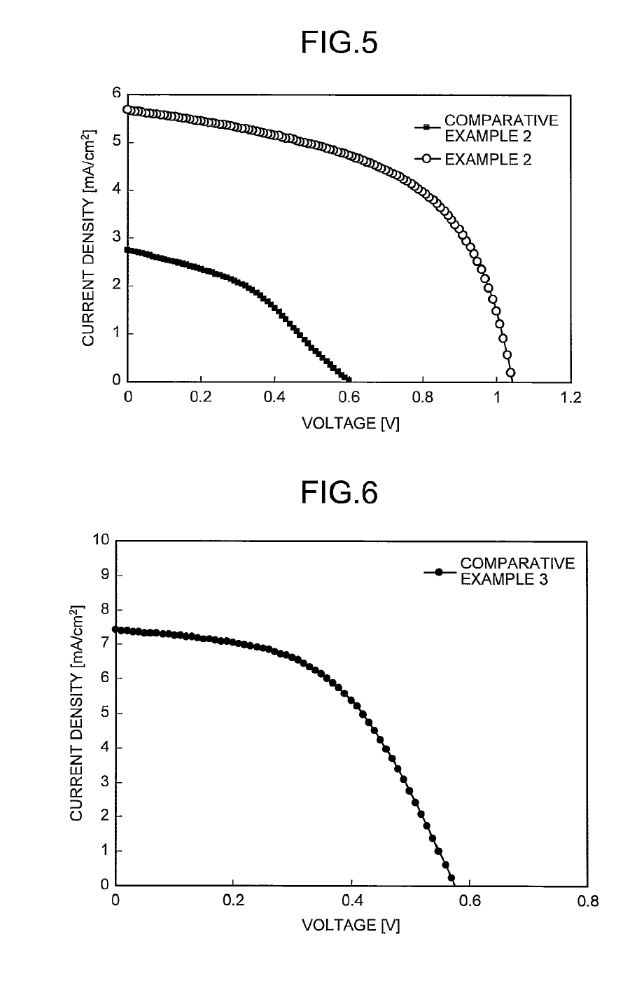

The organic thin-film solar cells, that were organic photovoltaic cells, obtained in Examples and Comparative Examples each had a regular tetragon-shape of 2 mm×2 mm. The organic thin-film solar cells were irradiated with constant light using a solar simulator (manufactured by BUNKOUKEIKI Co., Ltd., trade name: CEP-2000, irradiance: 100 mW/cm²) to measure the generated currents and voltages for calculation of photovoltaic efficiency. The short-circuit current densities, the open-circuit voltages, the fill factors, and the photovoltaic efficiency of the organic thin-film solar cells are illustrated in Table 1. The current-voltage characteristics of the organic thin-film solar cells in Example 1 and Comparative Example 1 are illustrated in FIG. 4, the current-voltage characteristics of the organic thin-film solar cells in Example 2 and Comparative Example 2 are illustrated in FIG. 5, and the current-voltage characteristics of the organic thin-film solar cell in Comparative Example 3 are illustrated in FIG. 5.

The organic thin-film solar cells in Examples 1 and 2 showed photovoltaic efficiency higher than ones of the organic thin-film solar cells in Comparative Examples 1 to 3.

TABLE 1

| | | | COMPARATIVE | COMPARATIVE | COMPARATIVE |
|---|---|---|---|---|---|
| | EXAMPLE 1 | EXAMPLE 2 | EXAMPLE 1 | EXAMPLE 2 | EXAMPLE 3 |
| SHORT-CIRCUIT | 11.34 | 5.67 | 7.52 | 2.75 | 7.40 |
| CURRENT DENSITY | | | | | |
| [mA/cm²] | | | | | |
| OPEN-CIRCUIT | 0.57 | 1.04 | 0.52 | 0.61 | 0.58 |
| CURRENT DENSITY | | | | | |
| [V] | | | | | |
| FILL FACTOR | 0.58 | 0.54 | 0.22 | 0.39 | 0.51 |
| PHOTOVOLTAIC | 3.77 | 3.19 | 0.87 | 0.65 | 2.18 |
| EFFICIENCY [%] | | | | | |

### INDUSTRIAL APPLICABILITY

The present invention provides an organic photovoltaic cell and a manufacturing method thereof, and therefore is useful.

1. An organic photovoltaic cell comprising:
a pair of electrodes; and
an active layer located between the pair of electrodes and comprising an organic compound, wherein
in the active layer, each content of inorganic compounds of a phosphorus compound, a palladium compound, an aluminum compound, an iron compound, a calcium compound, a potassium compound, and a sodium compound is 30 ppm by weight or less.

2. The organic photovoltaic cell according to claim 1, wherein the organic compound is an electron-donor compound that is purified using an adsorbent comprising silica gel and alumina.

3. An organic photovoltaic cell comprising:
a pair of electrodes; and
an active layer located between the pair of electrodes and comprising an organic compound, wherein
a content of a palladium compound in the active layer is 30 ppm by weight or less in terms of palladium.

4. An organic photovoltaic cell comprising:
a pair of electrodes; and
an active layer located between the pair of electrodes and comprising an organic compound, wherein
a content of a sodium compound in the active layer is 30 ppm by weight or less in terms of sodium.

5. An organic photovoltaic cell comprising:
a pair of electrodes; and
an active layer located between the pair of electrodes and comprising an organic compound, wherein
content of an iron compound in the active layer is 30 ppm by weight or less in terms of iron.

6. A manufacturing method of an organic photovoltaic cell comprising a pair of electrodes and an active layer that is located between the pair of electrodes and comprises an organic compound, the manufacturing method comprising:
purifying an electron-donor compound serving as the organic compound with an adsorbent comprising silica gel and alumina; and
forming a film of the active layer using a liquid comprising an organic compound that comprises the electron-donor compound after being purified.
